(19) United States
(12) Patent Application Publication
(10) Pub. No.: US 2005/0252602 A1
(43) Pub. Date: Nov. 17, 2005

(54) Organic thin-film device and its production method

(76) Inventor: Tomomi Tateishi, Kanagawa (JP)

Correspondence Address: BIRCH STEWART KOLASCH & BIRCH, PO BOX 747, FALLS CHURCH, VA, 22040-0747, US

(21) Appl. No.: 10/507,927

(22) PCT Filed: Mar. 19, 2003
(86) PCT No.: PCT/JP03/03331

§ 371 Date: Sep. 17, 2004

(30) Foreign Application Priority Data
Mar. 20, 2002 (JP) 2002-079123

(51) Int. Cl. G03C 8/00; B05D 5/06; H05B 33/10

(52) U.S. Cl. 156/230; 156/238; 430/200; 427/66

(57) ABSTRACT

A method for producing an organic thin-film device comprising the steps of (a) heating and/or pressing a transfer material having an organic thin-film layer formed on a temporary support and a first laminate comprising a substrate and at least a transparent conductive layer or a rear-surface electrode formed on the substrate, which are overlapped each other such that the organic thin-film layer of the transfer material faces a receiving surface of the first laminate, thereby forming a laminate structure; (b) peeling the temporary support from the laminate structure to transfer the organic thin-film layer to the receiving surface of the first laminate; and (c) bonding a second laminate comprising a substrate and at least a rear-surface electrode or a transparent conductive layer formed on the substrate to the organic thin-film layer transfer onto the first laminate.

### FIELD OF THE INVENTION

The present invention relates to a method for producing an organic thin-film device, preferably an organic electroluminescence (EL) device, effectively usable for plate light sources such as full-color display devices, backlights and illumination light sources, light source arrays of printers, etc., and an organic thin-film device produced by such a method.

### BACKGROUND OF THE INVENTION

Much attention is paid to organic light-emitting devices such as organic electroluminescence (EL) devices usable for surface-emitting devices. Specifically, promising as inexpensive, solid-emission-type, large-emission-area, full-color display devices and writing light source arrays, the organic light-emitting devices have been actively developed. The organic light-emitting device generally comprises a couple of electrodes (a transparent electrode and a rear-surface electrode), and a light-emitting, organic thin-film layer formed between the electrodes. When an electric field is applied to the organic light-emitting device, electrons are injected into the light-emitting, organic thin-film layer from the rear-surface electrode, while holes are injected thereinto from the transparent electrode. Electrons and holes are recombined in the light-emitting, organic thin-film layer, and an energy level is lowered from a conduction band to a valence band, whereby energy is turned to light, which is emitted from the organic light-emitting device.

The organic thin-film layers in the organic light-emitting devices are mostly formed by a vapor deposition method. For instance, JP 9-167684 A and JP 2000-195665 A propose methods comprising uniformly forming an organic layer on a temporary support of mica or a film by a vapor deposition method, bringing the organic layer close to the substrate, and carrying out a heating vapor deposition. However, these methods are poor in productivity because they use a vapor deposition method. In addition, because only low-molecular-weight organic compounds can be used for organic thin-film layers, the resultant organic light-emitting devices are insufficient in durability such as bending resistance, film strength, etc. when used for flexible displays, etc. This problem is serious particularly when they have large areas.

Also known are high-molecular-weight devices comprising high-molecular-weight, light-emitting, thin-film layers of poly(p-phenylenevinylene) generating green light (Nature, Vol. 347, page 539, 1990), poly(3-alkylthiophene) generating reddish orange light (The Japanese Journal of Applied Physics, Vol. 30, page L1938, 1991), polyalkylfluorene generating blue light (The Japanese Journal of Applied Physics, Vol. 30, page L1941, 1991), etc., light-emitting, thin-film layers constituted by low-molecular-weight compounds dispersed in binder resins. These devices having high-molecular-weight compounds are advantageous in making large-area, light-emitting devices, and their applications for flexible displays are expected. However, the vapor deposition method cannot be used to form the organic, light-emitting, thin-film layers. Accordingly, thin-film layers are generally formed directly on substrates by wet methods.

The wet methods are, however, disadvantageous in that the formed organic thin-film layers are insufficient in the uniformity of thickness because of the surface tension of solutions, and that when the organic thin-film layers are laminated, the organic thin-film layers tend to be dissolved in their interfaces. Accordingly, the organic thin-film devices obtained by the wet methods are poor in light-emitting efficiency and durability of devices.

WO 00/41893 discloses a method for thermally transferring an organic thin-film layer and a photo-thermal conversion layer onto a substrate by a laser beam by using a donor sheet having the organic thin-film layer and the photo-thermal conversion layer. Such a thermal transfer method is disadvantageous in that a gas often penetrates into an interface between the organic thin-film layer and the substrate. The light-emitting efficiency, durability and uniformity of the organic EL device vary depending on conditions of the interface of the organic thin-film layer, and the penetration of gas into the interface of the organic thin-film layer results in poor light-emitting properties.

In the case of thermal writing in a predetermined pattern using a thermal head or a laser common in printing technologies, a temperature distribution generated around an organic, thin-film pattern by thermal diffusion blurs its outline, failing to cut the organic, thin-film pattern from the donor accurately. Thus, organic light-emitting devices produced by this method are uneven in light emission and likely to suffer from poor durability, because of insufficient electric connection and the breakage of the organic thin-film layer. Further, yield is likely to be low because of low-accuracy positioning of the substrate and the thermal head or laser beam.

### OBJECTS OF THE INVENTION

Accordingly, an object of the present invention is to provide a method for producing an organic thin-film device such as an organic EL device, etc. by easily forming an organic thin-film layer having uniformity and good adhesion interface on a substrate, particularly a method for producing an organic thin-film device having excellent light-emitting efficiency, uniformity of light emission and durability by using a transfer material having a uniform, organic thin-film layer formed by a wet method.

Another object of the present invention is to provide an organic thin-film device produced by such a method.

### SUMMARY OF THE INVENTION

As a result of intense research in view of the above objects, the inventors have found that using a transfer material comprising an organic thin-film layer on a temporary support, a combination of the step of transferring the organic thin-film layer to a first laminate comprising a substrate and at least a transparent conductive layer or a rear-surface electrode formed on the substrate, and the step of bonding the organic thin-film layer to a second laminate comprising a substrate and at least a rear-surface electrode or a transparent conductive layer formed on the substrate makes it possible to produce an organic thin-film device such as an organic EL device, etc. excellent in light-emitting efficiency, uniformity of light emission and durability at a low cost. The present invention has been accomplished based on this finding.

Thus, the method of the present invention for producing an organic thin-film device comprises the steps of (a) heating and/or pressing a transfer material having an organic thin-film layer formed on a temporary support and a first laminate comprising a substrate and at least a transparent conductive layer or a rear-surface electrode formed on the substrate, which are overlapped each other such that the organic thin-film layer of the transfer material faces a receiving surface of the first laminate, thereby forming a laminate structure; (b) peeling the temporary support from the laminate structure to transfer the organic thin-film layer to the receiving surface of the first laminate; and (c) bonding a second laminate comprising a substrate and at least a rear-surface electrode or a transparent conductive layer formed on the substrate to the organic thin-film layer transferred onto the first laminate.

The step (a) preferably comprises heating and pressing. The heating means is preferably selected from the group consisting of a laminator, an infrared heater and a roller heater.

A light-emitting device uniformly emitting light can be produced by forming a transfer material by a wet method. The second laminate may have an organic thin-film layer formed on the rear-surface electrode or the transparent conductive layer. It is preferable that the first laminate and the second laminate respectively have a thermal expansion coefficient of 20 ppm/° C. or less. The organic thin-film layer preferably contains at least a light-emitting, organic compound and/or a carrier-transporting, organic compound.

A hole-transporting, organic thin-film layer, a light-emitting, organic thin-film layer and an electron-transporting, organic thin-film layer are successively transferred. At least one of the first laminate and the second laminate is preferably provided with a transparent conductive layer. The temporary support and/or the substrate are preferably in the form of a continuous web. The substrate is preferably made of at least one material selected from the group consisting of polyimides; polyesters; polycarbonates; polyether sulfone; metal foils such as aluminum foil, copper foil, stainless steel foil, gold foil, silver foil; plastic sheets of liquid crystal polymers; fluorine-containing polymers such as poly(chlorotrifluoroethylene), Teflon, polytetrafluoroethylene-polyethylene copolymers.

The organic thin-film device of the present invention is preferably produced by the above method. The above method for producing an organic thin-film device is applicable to the production of an organic electroluminescent device.

### BRIEF DESCRIPTION OF THE DRAWINGS

FIG. 1 is a schematic view showing one example of an apparatus for producing the organic thin-film device of the present invention.

### DETAILED DESCRIPTION OF THE PREFERRED EMBODIMENTS

[1] Transfer Material

(1) Structure

The transfer material comprises an organic thin-film layer formed on a temporary support. Though the transfer material may properly be produced by a known method, it is preferable to use a wet method from the aspects of light-emitting efficiency, uniformity of light emission, durability and productivity. The transfer material provided with the organic thin-film layer may be produced as separate transfer materials, or a plurality of successive planes each constituted by the organic thin-film layer may be formed on one temporary support. In the latter case, a plurality of organic thin-film layers can continuously be formed without necessitating the exchange of the transfer materials.

Alternatively, when a transfer material having two or more organic thin-film layers laminated in advance on a temporary support is used, a multi-layer, thin-film layer can be laminated on a receiving surface of the substrate by a single transfer step. In a case where the organic thin-film layers are laminated on a temporary support in advance, there would be ununiformity in the mobility of holes and electrons unless each organic thin-film layer laminated has a uniform interface. Accordingly, it is necessary to select a solvent cautiously to obtain a uniform interface, and it is necessary to select an organic compound for the organic thin-film layer, which is soluble in the above solvent.

(2) Temporary Support

The temporary support used in the present invention should be made of a material that has chemical stability, thermal stability and flexibility. Specific examples of the materials include fluororesins such as a tetrafluoroethylene resin (PTFE), a trifluorochloroethylene resin; polyesters such as polyethylene terephthalate and polyethylene naphthalate (PEN); polyarylates; polycarbonates; polyolefins such as polyethylene and polypropylene; polyether sulfone (PES); etc. The temporary support is particularly preferably a thin sheet made of at least one of these materials or a laminate thereof. The thickness of the temporary support is preferably 1 μm to 300 μm, more preferably 3 μm to 200 μm, particularly 3 μm to 50 μm.

The temporary support may be a single-layer sheet or a laminate sheet. In the case of the laminate sheet, it may have a substrate and at least one flat layer thereon on a side, on which the organic thin-film layer is formed. Materials making the flat layer are not particularly restrictive.

(3) Formation of Organic Thin-Film Layer on Temporary Support

An organic thin-film layer containing a high-molecular-weight compound as a binder is preferably formed on the temporary support by a wet method. Materials for the organic thin-film layer are dissolved in an organic solvent at a desired concentration, and the resultant solution is coated onto the temporary support. Coating methods are not particularly limited, as long as they can form the organic thin-film layer that has a thickness of 200 nm or less and a uniform thickness distribution after drying. Examples of the coating methods include a spin-coating method, a gravure-coating method, a dip-coating method, a casting method, a die-coating method, a roll-coating method, a bar-coating method, an extrusion-coating method, an ink-jet coating method, etc. Preferable among them is a high-productivity, roll-to-roll, extrusion-coating method.

(4) Organic Thin-Film Layer

The organic thin-film layer, which is a layer constituting the organic thin-film device, includes a light-emitting, organic thin-film layer, an electron-transporting, organic thin-film layer, a hole-transporting, organic thin-film layer, an electron-injecting layer, a hole-injecting layer, etc., depending on their characteristics. The organic thin-film layer does not have a photo-thermal conversion layer (layer capable of causing a photo-thermal conversion by laser beams). In addition, various layers for improving light emission may be included. Specific examples of compounds used in each organic thin-film layer are described in, for instance, “Organic EL Display” (Technotimes Co., Separate Volume of “Monthly Display,” the October issue of 1998), etc. The dry thickness of the organic thin-film layer is preferably 2 nm to 600 nm, more preferably 2 nm to 400 nm, further preferably 2 nm to 300 nn.

The glass transition temperature of the organic thin-film layer per se or components therein is preferably 40° C. or higher and a transfer temperature +40° C. or lower, further preferably 50° C. or higher and a transfer temperature +20° C. or lower, particularly 60° C. or higher and a transfer temperature or lower. The flow-starting temperature of the organic thin-film layer per se of the transfer material or components therein is preferably 40° C. or higher and a transfer temperature +40° C. or lower, more preferably 50° C. or higher and a transfer temperature +20° C. or lower, particularly 60° C. or higher and a transfer temperature or lower. The glass transition temperature can be measured by using a differential scanning calorimeter (DSC). The flow-starting temperature can be measured, for instance, by causing a sample to flow from an orifice of 1 mm of in inner diameter under a load of 20 Kg/cm² while heating at a constant temperature elevation speed, using FLOWTESTER CFT-500 available from Shimadzu Corporation.

(a) Light-Emitting, Organic Thin-Film Layer

The light-emitting, organic thin-film layer comprises at least one light-emitting compound. Though not restrictive, the light-emitting compound may be a fluorescent compound or a phosphorescent compound. The fluorescent compound and the phosphorescent compound may be used in combination. In the present invention, the phosphorescent compound is preferably used from the viewpoints of a light-emitting brightness and a light-emitting efficiency.

Examples of the fluorescent compound used in this invention include benzoxazole derivatives; benzoimidazole derivatives; benzothiazole derivatives; styrylbenzene derivatives; polyphenyl derivatives; diphenylbutadiene derivatives; tetraphenylbutadiene derivatives; naphthalinido derivatives; coumarin derivatives; perylene derivatives; perynone derivatives; oxadiazole derivatives; aldazine derivatives; pyralidine derivatives; cyclopentadiene derivatives; bis(styryl)anthracene derivatives; quinacridon derivatives; pyrrolopyridine derivatives; thiadiazolopylidine derivatives; styrylamine derivatives; aromatic dimethylidine compounds; metal complexes such as 8-quinolinol metal complexes and derivatives thereof and rare-earth metal complexes; light-emitting polymer material such as polythiophene derivatives, polyphenylene derivatives, polyphenylenevinylene derivatives and polyfluorene derivatives; etc. The fluorescent compounds may be used alone or in combination.

The phosphorescent compound preferably utilizes triplet excitons for light emission. The phosphorescent compound is preferably an ortho-metallation complex or a porphyrin complex. The porphyrin complex is preferably a porphyrin-platinum complex. The phosphorescent compounds may be used alone or in combination.

The ortho-metallation complex used in the present invention may be such a compound that is described in Akio Yamamoto, “Metalorganic Chemistry, Foundation and Application”, pages 150 to 232, Shokabo Publishing Co., Ltd., (1982); H. Yersin, “Photochemistry and Photophysics of Coordination Compounds,” pages 71 to 77 and 135 to 146, Springer-Verlag, Inc. (1987), etc. Although ligands of the ortho-metallation complexes are not particularly limited, the ortho-metallation complexes generally have particular ligands. Preferred examples of the particular ligands include 2-phenylpyridine derivatives, 7,8-benzoquinoline derivatives, 2-(2-thienyl) pyridine derivatives, 2-(1-naphthyl) pyridine derivatives and 2-phenylquinoline derivatives. The derivatives may have a substituent. The ortho-metallation complexes may have other ligands than the particular ligands. Center metal atoms of the ortho-metallation complexes may be selected from transition metals. The center metals are preferably rhodium, platinum, gold, iridium, ruthenium or palladium. The organic thin-film layer comprising such an ortho-metallation complex is excellent in the brightness of light emitted and light-emitting efficiency. Complexes disclosed in JP 2002-319491A may be used as the ortho-metallation complexes in the present invention.

The ortho-metallation complex used in the present invention may be synthesized by a known method disclosed in Inorg. Chem., 30, 1685, 1991; Inorg. Chem., 27, 3464, 1988; Inorg. Chem., 33, 545, 1994; Inorg. Chim. Acta, 181, 245, 1991; J. Organomet. Chem., 335, 293, 1987; J. Am. Chem. Soc., 107, 1431, 1985; etc.

Though not restrictive, the content of the light-emitting compound in the light-emitting, organic thin-film layer is, for instance, preferably 0.1 to 70% by mass, more preferably 1 to 20% by mass. When the content of the light-emitting compound is less than 0.1% by mass or more than 70% by mass, the effect of adding the light-emitting compound tends to be insufficient.

The light-emitting, organic thin-film layer may contain a host compound, a hole-transporting material, an electron-transporting material, an electrically inactive polymer binder, etc., if necessary. Incidentally, the functions of these materials may be able to be achieved by only one compound. For instance, a carbazole derivative function not only as a host compound but also as a hole-transporting material.

The host compound is a compound causing energy transfer from its excited state to the light-emitting compound, resulting in accelerating the light emission of the light-emitting compound. Examples of the host compounds include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, anthraquinodimethane derivatives, anthrone derivatives, diphenylquinone derivatives, thiopyran dioxide derivatives, carbodimide derivatives, fluorenylidenemethane derivatives, distyrylpyrazine derivatives, anhydrides derived from a heterocyclic tetracarboxylic acid having a structure such as naphthaleneperylene, phthalocyanine derivatives, 8-quinolinol metal complexes and derivatives thereof, metallophthalocyanines, metal complexes containing a benzoxazole ligand or a benzothiazole ligand, polysilane compounds, poly(N-vinylcarbazole) derivatives, aniline copolymers, electrically conductive polymers and oligomers such as oligothiophenes and polythiophenes, polythiophene derivatives, polyphenylene derivatives, polyphenylenevinylene derivatives, polyfluorene derivatives, etc. The host compounds may be used alone or in combination. The content of the host compound in the light-emitting, organic thin-film layer is preferably 0 to 99.9% by mass, more preferably 0 to 99.0% by mass.

Though not restrictive, the hole-transporting materials may be low-or high-molecular-weight materials if they have any of functions of injecting holes from the anode into the light-emitting, organic thin-film layer, transporting holes and blocking electrons from the cathode. Examples of the hole-transporting materials include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, polysilane compounds, poly(N-vinylcarbazole) derivatives, aniline copolymers, electrically conductive polymers and oligomers such as oligothiophenes and polythiophenes, polythiophene derivatives, polyphenylene derivatives, polyphenylenevinylene derivatives, polyfluorene derivatives, etc. These hole-transporting materials may be used alone or in combination. The content of the hole-transporting material in the light-emitting, organic thin-film layer is preferably 0 to 99.9% by mass, more preferably 0 to 80.0% by mass.

The electron-transporting materials are not particularly limited as long as they have any of functions of injecting electrons from the cathode into the light-emitting, organic thin-film layer, transporting electrons, and blocking holes from the anode. Examples of the electron-transporting materials include triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodimide derivatives, fluorenylidenemethane derivatives, distyrylpyrazine derivatives, anhydrides derived from a heterocyclic tetracarboxylic acid having a structure such as naphthaleneperylene, phthalocyanine derivatives, 8-quinolinol metal complexes and derivatives thereof, metallophthalocyanines, metal complexes containing a benzoxazole ligand or a benzothiazole ligand, aniline copolymers, electrically conductive polymers and oligomers such as oligothiophenes and polythiophenes, polythiophene derivatives, polyphenylene derivatives, polyphenylenevinylene derivatives, polyfluorene derivatives, etc. These electron-transporting materials may be used alone or in combination. The content of the electron-transporting material in the light-emitting, organic thin-film layer is preferably 0 to 99.9% by mass, more preferably 0 to 80.0% by mass.

Examples of usable polymer binders include polyvinyl chloride, polycarbonates, polystyrene, polymethyl methacrylate, polybutyl methacrylate, polyesters, polysulfones, polyphenylene oxide, polybutadiene, hydrocarbon resins, ketone resins, phenoxy resins, polyamides, ethyl cellulose, polyvinyl acetate, ABS resins, polyurethanes, melamine resins, unsaturated polyesters, alkyd resins, epoxy resins, silicone resins, polyvinyl butyral, polyvinyl acetal, etc. These polymer binders may be used alone or in combination. The light-emitting, organic thin-film layer containing at least one polymer binder can be easily formed with a large area by the wet film-forming method.

The dry thickness of the light-emitting, organic thin-film layer is preferably 2 nm to 600 nm, more preferably 2 nm to 400 nm, and particularly 2 nm to 300 nm. When the dry thickness of the light-emitting, organic thin-film layer exceeds 600 nm, driving voltage is likely to rise. On the other hand, when the thickness of the light-emitting, organic thin-film layer is less than 2 nm, short-circuiting is likely to occur in the organic thin-film device.

(b) Hole-Transporting, Organic Thin-Film Layer

The organic thin-film device may comprise a hole-transporting, organic thin-film layer made of the above hole-transporting material, if necessary. The hole-transporting, organic thin-film layer may contain the above polymer binder. The dry thickness of the hole-transporting, organic thin-film layer is preferably 2 nm to 600 nm, more preferably 2 nm to 400 mn, further preferably 2 nm to 300 nm. When the dry thickness exceeds 600 nm, driving voltage is likely to rise. On the other hand, when it is less than 2 nm, short-circuiting is likely to occur in the organic thin-film device.

(c) Electron-Transporting, Organic Thin-Film Layer

The organic thin-film device may have an electron-transporting, organic thin-film layer made of the above electron-transporting material, if necessary. The electron-transporting, organic thin-film layer may contain the above polymer binder. The dry thickness of the electron-transporting, organic thin-film layer is preferably 2 nm to 600 nm, more preferably 2 nm to 400 nm, further preferably 2 nm to 300 nm. When the dry thickness exceeds 600 nm, driving voltage is likely to rise. On the other hand, when it is less than 2 nm, short-circuiting is likely to occur in the organic thin-film device.

When the organic thin-film layer is formed by coating by a wet film-forming method, solvents used for preparing a coating solution by. dissolving materials for the organic thin-film layer are not particularly restrictive, but may be properly selected depending on the types of the hole-transporting materials, the ortho-metallation complexes, the host compounds, the polymer binders, etc. Examples of the solvents include halogen solvents such as chloroform, tetrachloromethane, dichloromethane, 1,2-dichloroethane and chlorobenzene; ketone solvents such as acetone, methyl ethyl ketone, diethyl ketone, n-propyl methyl ketone and cyclohexanone; aromatic solvents such as benzene, toluene and xylene; ester solvents such as ethyl acetate, n-propyl acetate, n-butyl acetate, methyl propionate, ethyl propionate, γ-butyrolactone and diethyl carbonate; ether solvents such as tetrahydrofuran and dioxane; amide solvents such as dimethylformamide and dimethylacetamide; dimethylsulfoxide, water; etc. A solid content of the coating solution for the organic thin-film layer is not particularly restrictive, and its viscosity may be arbitrarily selected depending on a wet film-forming method.

When a plurality of organic thin-film layers are formed, a dry film-forming method such as a vapor deposition method and a sputtering method, a wet film-forming method such as a dipping method, a spin-coating method, a dip-coating method, a casting method, a die-coating method, a roll-coating method, a bar-coating method and a gravare-coating method, a printing method, etc. may be used together with the transfer method.

[2] Production of Organic Thin-Film Device Using Transfer Material

The production method of the organic thin-film device of the present invention is characterized by using a transfer material having an organic thin-film layer formed on a temporary support, to carry out the step of transferring the organic thin-film layer to a first laminate comprising a substrate and at least a transparent conductive layer or a rear-surface electrode formed on the substrate by a peeling transfer method, and the step of bonding the organic thin-film layer formed by the peeling-transfer method to a second laminate comprising a substrate and at least a rear-surface electrode or a transparent conductive layer formed on the substrate.

Incidentally, the description to the effect that the organic thin-film layer is transferred to the first laminate and then bonded to the second laminate is simply for the purpose of convenience of explanation, and there is actually no restriction as to which laminate is the first laminate or the second laminate. Accordingly, though explanation below is concerned about a case where the organic thin-film layer is transferred to the first laminate, this explanation is applicable to transfer to the second laminate as it is.

The peeling transfer method comprises the steps of heating and/or pressing a transfer material overlapped onto a first laminate to soften an organic thin-film layer, which is adhered to a receiving surface of the first laminate, and peeling the temporary support so that. only the organic thin-film layer remains on the receiving surface. The bonding method is a method for bonding at least two members by adhesion, pressure-bonding, fusion, etc. Specifically, the organic thin-film layer transferred to the receiving surface of the first laminate comprising a substrate and at least a transparent conductive layer or a rear-surface electrode formed on the substrate is overlapped with the second laminate comprising a substrate and at least a rear-surface electrode or a transparent conductive layer formed on the substrate, which may have an organic thin-film layer, if necessary, and then heated and/or pressed to soften the organic thin-film layer, whereby the organic thin-film layer is bonded to the rear-surface electrode or the transparent conductive layer, or the organic thin-film layer, if any, of the second laminate. In the transfer method and the bonding method used in the present invention, heating and pressing may be carried out alone or in combination.

Heating may be generally carried out by a known means, and heating means such as a laminator, an infrared heater, a roller heater, a laser, a thermal head, etc. may be used. In the case of large-area transfer, surface-heating means are preferable, and a laminator, an infrared heater, a roller heater, etc. are more preferable. The transfer temperature may vary depending on the materials of the organic thin-film layer and the heating member. It is, however, preferably 40° C. to 250° C., more preferably 50° C. to 200° C., particularly 60° C. to 180° C. It should be noted that a preferred range of the transfer temperature is related to the heat resistance of the heating member, the transfer material and the substrate, meaning that as the heat resistance increases, the transfer temperature is elevated accordingly.

Though a pressing means is not particularly restrictive, those capable of conducting uniform pressing are preferable when a substrate such as glass, etc., which is easily broken by strain, is used. For instance, a pair of rollers, one or both of which are made of rubber, are preferable, specifically, a laminator such as First Laminator VA-400III available from Taisei Laminator K. K., a thermal head of a thermal transfer printer, etc. are preferable.

In the present invention, the step of transferring and the step of peeling may be repeated to laminate a plurality of organic thin-film layers on the laminate. A plurality of organic thin-film layers may have the same or different compositions. The same composition is advantageous in preventing the lack of a layer by poor transfer and peeling. In the case of providing different layers, it is possible to provide a design having improved light-emitting efficiency with separate functions assigned to different layers. It is possible to laminate, for instance, a transparent conductive layer/a light-emitting, organic thin-film layer/an electron-transporting; organic thin-film layer/an electron-injecting layer/a rear-surface electrode; a transparent conductive layer/a hole-injecting layer/a hole-transporting, organic thin-film layer/a light-emitting, organic thin-film layer/an electron-transporting, organic thin-film layer/an electron-injecting layer/a rear-surface electrode onto a receiving surface by the transfer method of the present invention. In this case, lest that a previous transfer layer is reversely transferred to a next transfer layer, the heating temperature of the previous transfer material is preferably higher than that of the next transfer material.

The organic thin-film layer transferred onto the first laminate, or a new organic thin-film layer transferred onto the previously transferred organic thin-film layer is preferably reheated, if necessary. The organic thin-film layer is further strongly adhered to the first laminate or the previously transferred organic thin-film layer by reheating. At the time of reheating, pressing is preferably carried out, if necessary. The reheating temperature is preferably in the range of a transfer temperature ±50° C.

A surface treatment for improving the adhesiveness of a receiving surface may be carried out between the previous transferring step and the next transferring step, such that the previous transfer layer is not reversely transferred onto the next transfer layer. Such surface treatment includes, for instance, an activation treatment such as a corona discharge treatment, a flame treatment, a glow discharge treatment, a plasma treatment, etc. When the surface treatment is carried out, the transfer temperature of the previous transfer material may be lower than that of the next transfer material, unless reverse transfer occurs.

Usable as an apparatus for producing the organic thin-film device is an apparatus comprising a means for supplying the transfer material having an organic thin-film layer formed on a temporary support, a means for pressing the transfer material to a receiving surface of the first laminate while heating to transfer the organic thin-film layer to the receiving surface of the first laminate, and a means for peeling the temporary support from the organic thin-film layer after transfer.

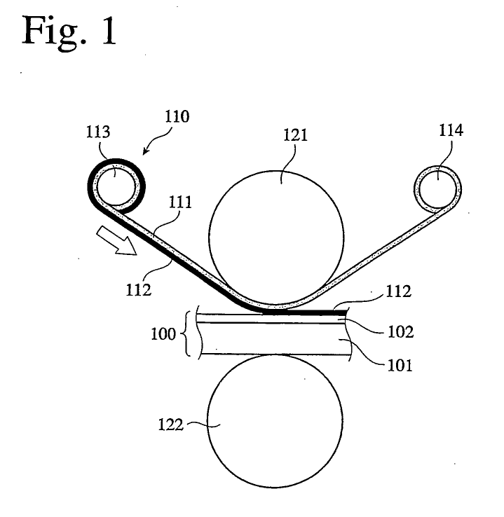

FIG. 1 shows one example of apparatuses for carrying out the method of the present invention for producing the organic thin-film device. The transfer material 110 having an organic thin-film layer 112 formed on a temporary support 111 is supplied from a transfer material-winding roll 113. A transfer apparatus comprises a heating (pressing) roll 121 and a pressing (heating) roll 122. A first laminate 100 constituted by a substrate 101 and a transparent conductive layer (cathode or anode) 102 is arranged between the heating (pressing) roll 121 and the pressing (heating) roll 122, and a transfer material 110 is supplied between the heating (pressing) roll 121 and the transparent conductive layer 102 of the first laminate 100, such that the transparent conductive layer 102 of the first laminate 100 is brought into contact with the organic thin-film layer 112 of the transfer material 110. By heating or pressing by the heating (pressing) roll 121, or by heating while pressing by the heating dressing) roll 121 and the pressing (heating) roll 122, the organic thin-film layer 112 is transferred onto the transparent conductive layer 102 of the first laminate 100. The remaining temporary support 111 is wound by a temporary support-winding roll 114.

The production apparatus used in the present invention preferably comprises a means for preheating a transfer material 110 and/or a first laminate 100 before supplying it to a transfer apparatus. A cooling apparatus is preferably provided downstream of the transfer apparatus. A means for adjusting the angle of the transfer material 110 to the first laminate 100 to 90° or less is preferably disposed on a front surface of the transfer apparatus. Also, a means for adjusting a peeling angle of the temporary support 111 from the organic thin-film layer 112 to 90° or more is preferably disposed on a rear surface of the transfer apparatus or the cooling apparatus. Methods and apparatuses for producing an organic thin-film device are described in detail in JP 2002-289346 A, etc.

[3] Organic Thin-Film Device (Organic Electroluminescent Device)

(1) Structure

The device comprises at least one organic compound layer containing a light-emitting layer between a pair of electrodes. The preferable overall structure of the organic thin-film device may be the following laminate structure formed on a substrate in this order or in an opposite order:
(a) transparent conductive layer/light-emitting, organic thin-film layer/rear-surface electrode;
(b) transparent conductive layer/light-emitting, organic thin-film layer/electron-transporting, organic thin-film layer/rear-surface electrode;
(c) transparent conductive layer/hole-transporting, organic thin-film layer/light-emitting, organic thin-film layer/electron-transporting, organic thin-film layer/rear-surface electrode;
(d) transparent conductive layer/hole-transporting, organic thin-film layer/light-emitting, organic thin-film layer/rear-surface electrode;
(e) transparent conductive layer/light-emitting, organic thin-film layer/electron-transporting, organic thin-film layer/electron-injecting layer/rear-surface electrode;
(f) transparent conductive layer/hole-injecting layer/hole-transporting, organic thin-film layer/light-emitting, organic thin-film layer/electron-transporting, organic thin-film layer/electron-injecting layer/rear-surface electrode, etc.

The light-emitting, organic thin-film layer comprises a fluorescent compound and/or a phosphorescent compound, and the emitted light is generally taken out from the transparent conductive layer. Specific examples of compounds used in each organic thin-film layer are described, for instance, in “Organic EL Display” (Technotimes Co., Separate Volume of “Monthly Display,” the October issue of 1998), etc.

(2) Substrate

Examples of materials used for the substrate include inorganic materials such as yttrium-stabilized zirconia (YSZ) and glass; polymers such as polyesters (polyethylene terephthalate, polybutylene terephthalate, polyethylene naphthalate, etc.), polystyrenes, polycarbonates, polyether sulfone, polyarylates, allyldiglycolcarbonate, polyimides, polycyclolefins, norbornene resins, poly(chlorotrifluoroethylene), Teflon, polytetrafluoroethylene-polyethylene copolymers; metal foils such as aluminum foil, copper foil, stainless steel foil, gold foil, silver foil; plastic sheets of polyimides, liquid crystal polymers; etc. In the present invention, it is preferable to use flexible substrates from the viewpoint of resistance to breakage, easiness of bending, low weight, etc. Materials for forming such substrate are preferably polyimides; polyesters; polycarbonates; polyether sulfone; metal foils such as aluminum foil, copper foil, stainless steel foil, gold foil, silver foil; plastic sheets of liquid crystal polymers; fluorine-containing polymers such as poly(chlorotrifluoroethylene), Teflon, polytetrafluoroethylene-polyethylene copolymers, etc., which are excellent in heat resistance, dimensional stability, solvent resistance, electric insulation and workability with little gas permeability and hygroscopicity.

The shape, structure and size of the substrate may be appropriately determined in accordance with purposes and applications of the organic thin-film device. The substrate is generally in a shape of plate or sheet. The substrate may have a single-layer structure or a multi-layer structure. The substrate may be composed of one member or a plurality of members. The substrate may be transparent or opaque. When the emitted light is taken out from the support side for such a reason that the transparent electrode described later is disposed on the substrate side than the organic layer including the light-emitting layer, the substrate is preferably colorless transparent or colored transparent, more preferably colorless transparent so that light emitted from the light-emitting, organic thin-film layer is not scattered or attenuated.

Preferable as a flexibility substrate for the light-emitting device provided with electrodes is a substrate constituted by adhering an insulating layer to one or both sides of a metal foil. Though not particularly restrictive, the metal foils may be an aluminum foil, a copper foil, a stainless steel foil, a gold foil, a silver foil, etc. Preferable among them are an aluminum foil and a copper foil from the viewpoint of easiness of working and cost. The insulating layer is not particularly restrictive, and may be made of, for instance, ceramics such as inorganic oxides and inorganic nitrides, plastics such as polyesters (for instance, polyethylene terephthalate, polybutylene terephthalate, polyethylene naphthalate), polystyrenes, polycarbonates, polyether sulfone, polyarylates, allyldiglycolcarbonate, polyimides, polycyclolefins, norbornene resins, poly(chlorotrifluoroethylene), polyimides, etc.

The substrate preferably has a linear thermal expansion coefficient of 20 ppm/° C. or less. The thermal expansion coefficient can be measured by a method of heating a sample at a constant speed to detect the change of its length, for instance, by a TMA method. When the linear thermal expansion coefficient is larger than 20 ppm/° C., the peeling of the electrodes and the organic thin-film layer is likely to occur by heat at the time of bonding or during use, etc., resulting in the deterioration of durability.

The insulating layer formed on the substrate also preferably has a linear thermal expansion coefficient of 20 ppm/° C. or less. Materials for forming the insulating layer having a linear thermal expansion coefficient of 20 ppm/° C. or less are preferably metal oxides such as silicon oxide, germanium oxide, zinc oxide, aluminum oxide, titanium oxide, copper oxide; metal nitrides such as silicon nitride, germanium nitride, aluminum nitride, one or more of which may be combined. The inorganic insulating layer of metal oxides and/or metal nitrides preferably a thickness of 10 to 1000 nm. When the inorganic insulating layer is thinner than 10 nm, it has too low insulation. On the other hand, when the inorganic insulating layer is thicker than 1,000 nm, cracking is likely to occur, resulting in pinholes and thus lower insulation. The methods for forming an insulating layer of metal oxides and/or metal nitrides are not particularly restrictive, but dry methods such as a vapor deposition method, a sputtering method and a CVD method, wet methods such as a sol-gel method, methods of coating particles of metal oxides and/or metal nitrides dispersed in solvents, etc. may be used.

Particularly preferable as plastic materials having linear thermal expansion coefficients of 20 ppm or less are polyimides and liquid crystal polymers. The details of properties, etc. of these plastic materials are described in “Plastic Databook” edited by “Plastic” Editorial Department issued by Asahi Kasei AMIDAS, etc. When polyimides, etc. are used for an insulating layer, sheets of polyimides, etc. are preferably laminated with aluminum foils. A sheet of polyimides, etc. preferably has a thickness of 10 to 200 μm. When the sheet of polyimide, etc. is thinner than 10 μm, handling is difficult at the time of lamination. On the other hand, when the sheet of polyimide, etc. is thicker than 200 μm, it has poor flexibility, resulting in inconvenience in handling. The insulating layer may be attached to one or both sides of a metal foil. When it is attached to both sides, both sides may be metal oxides and/or metal nitrides, or both sides may be insulating layers of plastics such as polyimides. Alternatively, one side may be an insulating layer made of a metal oxide and/or a metal nitride, while the other side may be an insulating layer constituted by a polyimide sheet. Further, a hard coating layer and an undercoating layer may be formed, if necessary.

A moisture permeation-inhibiting layer (gas barrier layer) may be formed on one or both surfaces of the substrate. The gas barrier layer is preferably made of an inorganic compound such as silicon nitride, silicon oxide, etc. The gas barrier layer can be formed by a radio frequency sputtering method, etc. Further, a hard coating layer and an undercoating layer may be formed on the substrate, if necessary.

It is preferable to use a substrate having an insulating layer adhered to one or both sides of a metal foil. The metal foil is not particularly limited, and metal foil such as an aluminum foil, a copper foil, a stainless steel foil, a gold foil, a silver foil, etc. may be used. Among them, an aluminum or copper foil is preferable from the viewpoint of the easiness of working and cost. The insulating layer is not particularly limited, and may be formed, for instance, by inorganic materials such as inorganic oxides or nitrides, plastics such as polyesters (polyethylene terephthalate, polybutylene terephthalate, polyethylene naphthalate, etc.), polystyrenes, polycarbonates, polyether sulfone, polyarylates, allyldiglycolcarbonate, polyimides, polycyclolefins, norbornene resins, poly(chlorotrifluoroethylene), polyimide, etc.

The substrate has water permeability of preferably 0.1 g/m² day or less, more preferably 0.05 g/m² day or less, particularly 0.01 g/m² day or less. Its oxygen permeability is preferably 0.1 ml/m² day atm or less, more preferably 0.05 ml/m² day atm or less, particularly 0.01 ml/m² day atm or less. The water permeability can be measured according to a method of JISK7129B method (mainly MOCON method). The oxygen permeability can be measured by a method (mainly MOCON method) according to JISK7126B. With this, it is possible to prevent the intrusion of water and oxygen causing the deterioration of durability into the light-emitting device.

(3) Electrode (Cathode or Anode)

Both of the transparent conductive layer and the rear-surface electrode may be used as a cathode or an anode, which is determined by the composition of the organic thin-film device. The shape, structure and size of an anode usually is not restrictive as far as an anode functions to supply holes to the organic thin-film layer, and may be properly selected from known electrodes in accordance with the applications and purposes of the organic thin-film device.

The anode may be made of metals, alloys, metal oxides, electrically conductive compounds, mixtures thereof, etc. The anode is preferably made of a material having a work function of 4 eV or more. Examples of the materials for the anode include antimony-doped tin oxide (ATO); fluorine-doped tin oxide (FTO); semiconductive metal oxides such as tin oxide, zinc oxide, indium oxide, indium tin oxide (ITO) and indium zinc oxide (IZO); metals such as gold, silver, chromium and nickel; mixtures and laminates of the metals and conductive metal oxides; inorganic, conductive compounds such as copper iodide and copper sulfide; organic, conductive compounds such as polyaniline, polythiophene and polypyrrole; laminates of the organic, conductive compounds and ITO; etc.

The cathode may be made of metals, alloys, metal oxides, electrically conductive compounds, mixtures thereof, etc. The cathode is preferably made of a material having a work function of 4.5 eV or less. Examples of the materials used for the cathode include alkali metals such as Li, Na, K and Cs; alkaline earth metals such as Mg and Ca; gold; silver; lead; aluminum; a sodium-potassium alloy; a lithium-aluminum alloy; a magnesium-silver alloy; indium; rare earth metals such as ytterbium; etc. Although the materials may be used alone, the cathode is preferably made of a plurality of materials to improve both of stability and electron injection property.

Preferable among the above materials are alkali metals and alkaline earth metals from the viewpoint of the electron injection property, and aluminum-based materials from the viewpoint of stability during storage. Usable as the aluminum-based materials are aluminum itself and aluminum-based alloys and mixtures containing 0.01 to 10% by mass of alkali metals or alkaline earth metals, such as a lithium-aluminum alloy, a magnesium-aluminum alloy, etc.

When light is taken out from the cathode side, a transparent cathode should be used. The transparent cathode need only be substantially transparent to the light. To meet both requirements of electron injection and transparency, the transparent cathode may have a two-layer structure consisting of a thin metal layer and a transparent conductive layer. The materials for the thin metal layer are described in JP 2-15595 A, JP 5-121172 A, etc. The thin metal layer preferably has a thickness of 1 to 50 nm. When the thickness of the thin metal layer is less than 1 nm, it is difficult to provide the thin metal layer with a uniform thickness. On the other hand, when it is more than 50 nm, the thin metal layer has poor transparency to light.

Materials for the transparent conductive layer are not particularly restrictive as long as they are transparent materials having conductivity or semi-conductivity, and preferably those used for the above anode. The preferable materials include antimony-doped tin oxide (ATO), fluorine-doped tin oxide (FTO), tin oxide, zinc oxide, indium oxide, indium tin oxide (ITO), indium zinc oxide (IZO), etc. The thickness of the transparent conductive layer is preferably 30 to 500 nm. When transparent conductive layer is thinner than 30 nm, it has poor conductivity or semi-conductivity. On the other hand, when it exceeds 500 nm, its productivity is poor.

The formation method of the cathode is not restrictive, and known methods can be used, though it is carried out preferably in a vacuum apparatus. For instance, physical methods such as a vacuum deposition method, a sputtering method and an ion-plating method; chemical methods such as a CVD method and a plasma CVD method; etc. may be used to form the cathode. The formation method may be properly selected depending on the adaptability of the material to the cathode. In the case of using a plurality of materials for the cathode, the materials may be spattered simultaneously or successively. When the cathode material is an organic conductive material, a wet film-forming method may be used. The anode may be formed in the same manner as in the cathode.

The patterning of the cathode may be conducted by a chemical etching method such as a photolithography method or a physical etching method using laser beams, etc. In addition, the cathode may be patterned by vacuum vapor deposition or sputtering with a mask, a lift-off method, a printing method, etc. The patterning of the anode may be the same as in the case of the cathode.

Further, a dielectric layer may be formed between the cathode and the organic thin-film layer. The dielectric layer may be made of a fluoride of alkali or alkaline earth metal, having a thickness of 0.1 nm to 5 nm. The dielectric layer may be formed by a vacuum vapor deposition method, a sputtering method, an ion-plating method, etc.

(4) Patterning

To form the organic thin-film layer in a fine pattern, a mask (fine mask) having openings in a fine pattern is used. Though not restrictive, the mask is preferably made of highly durable, inexpensive materials such as metals, glass, ceramics, heat-resistant resins, etc. A plurality of materials may be used in combination. The thickness of the mask is preferably 2 μm to 100 μm, more preferably 5 μm to 60 μm from the viewpoint of mechanical strength and the transfer accuracy of the organic thin-film layer.

The mask preferably has tapered openings having larger diameters on the transfer material side than the substrate side, in order that the organic thin-film layer of the transfer material is adhered to an underlayer (the transparent conductive layer or the other organic thin-film layer) in precisely the same shape as each opening of the mask.

It is also preferable to use a patterning method, in which a substrate is overlapped with a transfer material surface provided with a ragged pattern, so that an organic thin-film layer formed in recesses of the transfer material is transferred to the first substrate. With a press member having a surface raggedness in a predetermined pattern pressed onto a surface of the organic thin-film layer formed on the temporary support of the transfer material, the surface of the transfer material can be provided with a ragged pattern corresponding to that of the press member. By repeating transfer to the first substrate with a plurality of transfer materials having organic thin-film layers having different compositions, it is possible to produce an organic thin-film device formed with a plurality of organic thin-film layers having different compositions.

(5) Other Layers

As layers constituting the organic thin-film device, it is preferable to form a protection layer and a sealing layer to prevent the light-emitting performance from deteriorating. The transfer material may further be provided with a peeling layer between the temporary support and the organic thin-film layer, and an adhesive layer between the organic thin-film layer and the receiving surface to improve transferability, unless the light-emitting performance is affected.

(a) Protective Layer

The organic thin-film device of the present invention may comprise the protective layer disclosed in JP 7-85974 A, JP 7-192866 A, JP 8-22891 A, JP 10-275682 A and JP 10-106746 A, etc. The protective layer is generally formed on the uppermost surface of the organic thin-film device. For example, in the organic thin-film device in which the substrate, the transparent conductive layer, the organic thin-film layers and the rear-surface electrode are formed in this order, the uppermost surface is the outer surface of the rear-surface electrode. Further, for instance, in the organic thin-film device in which the substrate, the rear-surface electrode, the organic thin-film layers and the transparent conductive layer are formed in this order, the uppermost surface is the outer surface of the transparent conductive layer. The shape, size and thickness of the protective layer are not particularly limited. The protective layer may be made of any material that can prevent substances such as water and oxygen degrading the function of the organic thin-film device from entering or penetrating into the device. Silicon monoxide, silicon dioxide, germanium monoxide, germanium dioxide, etc. may be used for the protective layer.

Though not restrictive, the protective layer may be formed by a vacuum deposition method, a spuffering method, an activated sputtering method, a molecular beam epitaxy (MBE) method, a cluster ion beam method, an ion-plating method, a plasma polymerization method, a plasma CVD method, a laser CVD method, a thermal CVD method, a coating method, etc.

(1b) Sealing Layer

The sealing layer is preferably formed in the organic thin-film device to prevent water and oxygen from entering or permeating into the device. Examples of materials for the sealing layer include copolymers of tetrafluoroethylene and at least one comonomer, fluorine-containing copolymers having cyclic structures in their main chains, polyethylene, polypropylene, polymethyl methacrylate, polyimides, polyureas, polytetrafluoroethylene, polychlorotrifluoroethylene, polydichlorodifluoroethylene, copolymers of chlorotrifluoroethylene or dichlorodifluoroethylene and other comonomers, moisture-absorbing substances having water absorption of 1% or more, moisture-resistant substances having a water absorption of 0.1% or less, metals such as In, Sn, Pb, Au, Cu, Ag, Al, Ti and Ni, metal oxides such as MgO, SiO, SiO₂, Al₂O₃, GeO, NiO, CaO, BaO, Fe₂O₃, Y₂O₃ and TiO₂, metal fluorides such as MgF₂, LiF, AiF₃ and CaF₂, liquid fluorinated carbons such as perfluoroalkanes, perfluoroamines and perfluoroethers, dispersions prepared by adding substances for adsorbing moisture or oxygen to liquid fluorinated carbons, etc.

The organic compound layers are preferably sealed by sealing parts such as sealing plates and sealing containers to shield the device from moisture, oxygen, etc. from outside. The sealing parts may be formed only on the rear-surface electrode side. Alternatively, the entire light-emitting structure may be covered with the sealing parts. The shape, size and thickness of the sealing parts are not particularly limited as long as the sealing parts can seal and shield the organic compound layer from outside air. The sealing parts may be made of glass, stainless steel, metals such as aluminum, plastics such as polychlorotrifluoroethylene, polyesters and polycarbonates, ceramics, etc.

A sealing agent or an adhesive may be used to form the sealing parts on the light-emitting structure. In the case of covering the entire light-emitting structure with the sealing parts, the sealing parts may be partially heat-welded with each other without using a sealing agent. Usable as the sealing agent are ultraviolet-curing resins, thermosetting resins, two-part-type hardening resins, etc.

Further, a water-absorbing agent or an inert liquid may be filled between the light-emitting structure and the sealing parts. Though not restrictive, the water-absorbing agents may be barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, a molecular sieve, a zeolite, magnesium oxide, etc. Though not restrictive, the inert liquids may be paraffins, liquid paraffins, fluorine-containing solvents such as perfluoroalkanes, perfluoroamines and perfluorethers; chlorine-containing solvents; a silicone oil, etc.

Light can be emitted from the organic thin-film device of the present invention by applying DC voltage of usually 2 to 40 V, which may contain an AC component, if necessary, or DC current between an anode and a cathode. With respect to the driving method of the light-emitting device, methods described in JP 2-148687 A, JP 6-301355 A, JP 5-29080 A, JP 7-134558 A, JP 8-234685 A, JP 8-241047 A, U.S. Pat. No. 5,828,429, 6,023,308, Japanese Patent 2784615, etc. may be utilized.

The present invention will be explained in further detail by Examples below without intention of restricting the scope of the present invention defined by the claims attached hereto.

### EXAMPLES 1 TO 20, COMPARATIVE EXAMPLES 1 TO 4

(A) Production of Laminate A

A glass plate of 0.5 mm×2.5 cm×2.5 cm was introduced into a washing vessel and washed with isopropyl alcohol (IPA), and then subjected to an oxygen plasma treatment. With a patterned vapor deposition mask having a light-emitting area of 5 mm×5 mm placed on one side of the oxygen plasma-treated glass plate, Al was vapor-deposited onto the glass plate in a reduced pressure atmosphere of about 0.1 mPa to form a 0.3-μn-thick electrode. Further as a dielectric layer, LiF was vapor-deposited onto the Al layer in a thickness of 3 nm in the same pattern as that of the Al layer. Aluminum lead wires were connected to Al electrodes to form Laminate A.

(B) Production of Laminate B

Laminate B was produced in the same manner as in Laminate A except for using a 50-μm-thick polyimide film (JPILEX-50S, available from Ube Industries, Ltd.) cut to 25 mm each in place of the glass plate.

(C) Production of Laminate C

A glass plate of 0.5 mm×2.5 cm×2.5 cm was introduced into a washing vessel and washed with isopropyl alcohol (IPA), and then subjected to an oxygen plasma treatment. With a patterned vapor deposition mask having a light-emitting area of 5 mm×5 mm placed on one side of the oxygen plasma-treated glass plate, Al was vapor-deposited onto the glass plate in a reduced pressure atmosphere of about 0.1 mPa to form a 0.3-μm-thick electrode. Further, as a dielectric layer, LiF was vapor-deposited onto the Al layer in a thickness of 3 mn in the same pattern as that of the Al layer. Aluminum lead wires were connected to Al electrodes. Next, an electron-transporting compound having the structure: 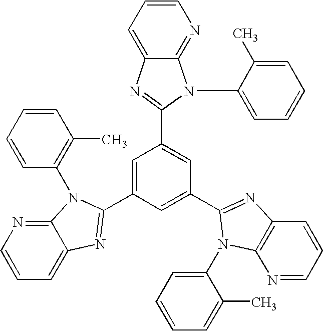
was vapor-deposited in a reduced pressure atmosphere of about 0.1 mPa, to form an electron-transporting, organic thin-film layer in a thickness of 9 nm on the LiF.
(D) Production of Laminate D

Laminate D was produced in the same manner as in Laminate C except for using a 50-μm-thick polyimide film (UPILEX-50S, available from Ube Industries, Ltd.) cut to 25 mm each in place of the glass plate.

(E) Production of Laminate E

A glass plate of 0.5 mm×2.5 cm×2.5 cm was introduced into a washing vessel and washed with isopropyl alcohol (IPA), and then subjected to an oxygen plasma treatment. With a patterned vapor deposition mask having a light-emitting area of 5 mm×5 mm placed on one side of the oxygen plasma-treated glass plate, Al was vapor-deposited onto the glass plate in a reduced pressure atmosphere of about 0.1 mPa to form a 0.3-μm-thick electrode. Further, as a dielectric layer, LiF was vapor-deposited onto the Al layer in a thickness of 3 nm in the same pattern as that of the Al layer. Aluminum lead wires were connected to Al electrodes to form a laminate structure.

Applied to the resultant laminate structure by a spin coating apparatus was a coating solution for an electron-transporting, organic thin-film layer having a composition of 10 parts by mass of polyvinylbutyral 2000L (Mw=2,000, available from Denki Kagaku Kogyo Kabushiki Kaisha), 20 parts by mass of an electron-transporting compound having the structural formula: 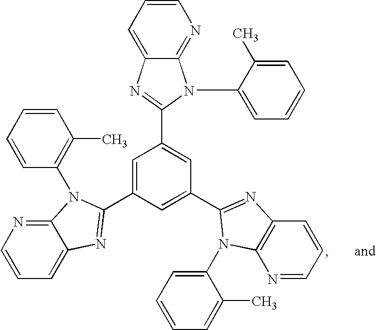
3,500 parts by mass of 1-butanol. The coated liquid was dried at 80° C. in vacuum for 2 hours, to form an electron-transporting, organic thin-film layer in a thickness of 15 nm on the LiF.
(F) Production of Laminate F

Laminate F was produced in the same manner as in Laminate E except for using a 50-μm-thick polyimide film (UPILEX-50S, available from Ube Industries, Ltd.) cut to 25 mm each in place of the glass plate.

(G) Production of Laminate G

A glass plate of 0.5 mm×2.5 cm×2.5 cm was placed in a vacuum chamber, to form transparent ITO electrodes thereon by DC magnetron sputtering using an ITO target under the conditions that the substrate was at a temperature of 250° C. and an oxygen pressure was 1×10⁻³ Pa. The ITO target contained 10% by mass of SnO₂ with an indium/tin molar ratio of 95/5. The transparent ITO electrodes had a thickness of 0.2 μm and a surface resistance of 10 Ω/square. Aluminum lead wires were connected to transparent ITO electrodes, to form a laminate structure. The glass plate provided with the transparent electrodes was introduced into a washing vessel and washed with isopropyl alcohol (IPA), and then subjected to an oxygen plasma treatment. The oxygen-plasma-treated, transparent ITO electrodes were spin-coated with an aqueous dispersion of polyethylenedioxythiophene and polystyrenesulfonate (“Baytron P” available from BAYER AG.) having a solid content of 1.3% by mass and vacuum-dried at 150° C. for 2 hours to form a hole-transporting, organic thin-film layer having a thickness of 100 nm.

(H) Production of Laminate H

Laminate H was produced in the same manner as in Laminate G except for using a 50-μm-thick polyimide film (UPILEX-50S, available from Ube Industries, Ltd.) cut to 25 mm each in place of the glass plate.

(I) Production of Laminate I

A glass plate of 0.5 mm×2.5 cm×2.5 cm was placed in a vacuum chamber, to form transparent ITO electrodes thereon by DC magnetron sputtering using an ITO target under the conditions that the substrate was at a temperature of 250° C. and an oxygen pressure was 1×10⁻³ Pa. The ITO target contained 10% by mass of SnO₂ with an indium/tin molar ratio of 95/5. The transparent ITO electrodes had a thickness of 0.2 μm and a surface resistance of 10 Ω/square. Aluminum lead wires were connected to transparent ITO electrodes to form a laminate structure. The glass plate provided with the transparent electrodes was introduced into a washing vessel and washed with isopropyl alcohol (IPA), and then subjected to an oxygen plasma treatment. Spin-coated to the treated transparent electrodes was a coating solution for a hole-transporting, organic thin-film layer having a composition of 40 parts by mass of a hole-transporting compound (PTPDES) represented by the structural formula: 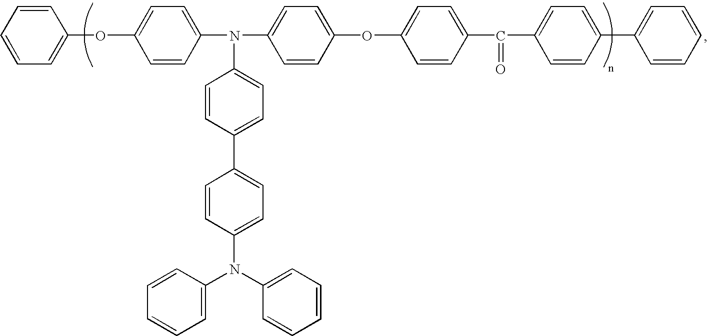
10 parts by mass of an additive (TBPA) represented by the structural formula: 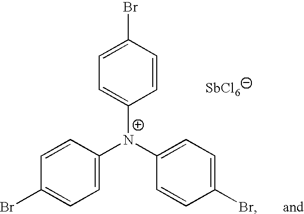
3, 200 parts by mass of dichloroethane. The coated liquid was dried at room temperature to form a hole-transporting, organic thin-film layer in a thickness of 100 nm.
(J) Production of Laminate J

Laminate J was produced in the same manner as in Laminate I except for using a 50-μm-thick polyimide film (UPILEX-50S, available from Ube Industries, Ltd.) cut to 25 mm each in place of the glass plate.

(K) Production of Laminate K

A glass plate of 0.5 mm×2.5 cm×2.5 cm was placed in a vacuum chamber, to form transparent ITO electrodes thereon by DC magnetron sputtering using an ITO target under the conditions that the substrate was at a temperature of 250° C. and an oxygen pressure was 1×10⁻³ Pa. The ITO target contained 10% by mass of SnO₂ with an indium/tin molar ratio of 95/5. The transparent ITO electrodes had a thickness of 0.2 μm and a surface resistance of 10 Ω/square. Aluminum lead wires were connected to the transparent ITO electrodes to form Laminate K. Laminate K was introduced into a washing vessel and washed with isopropyl alcohol (IPA), and then subjected to an oxygen plasma treatment.

(L) Production of Laminate L

Laminate L was produced in the same manner as in Laminate K except for using a 50-μm-thick polyimide film (UPILEX-50S, available from Ube Industries, Ltd.) cut to 25 mm each in place of the glass plate.

(M) Production of Transfer Material M

Spin-coated onto one side of a 188-μm-thick temporary support made of polyether sulfone available from Sumitomo Bakelite Co., Ltd. was a coating solution for a light-emitting, organic thin-film layer having a composition of 40 parts by mass of polyvinyl carbazole having Mw of 63,000 available from Aldrich Chemical Co., 1 part by mass of tris(2-phenylpyridine) iridium complex (ortho-metallation complex), and 3,200 parts by mass of dichloroethane. The coated liquid was dried at room temperature to form the light-emitting, organic thin-film layer in a thickness of 13 nm on the temporary support.

(N) Production of Transfer Material N

Spin-coated onto one side of a 188-μm-thick temporary support made of polyether sulfone available from Sumitomo Bakelite Co., Ltd. was a coating solution for an electron-transporting, organic thin-film layer having a composition having 10 parts by mass of polyvinylbutyral 2000L (Mw=2,000, available from Denki Kagaku Kogyo Kabushiki Kaisha), 20 parts by mass of an electron-transporting compound having the structure: 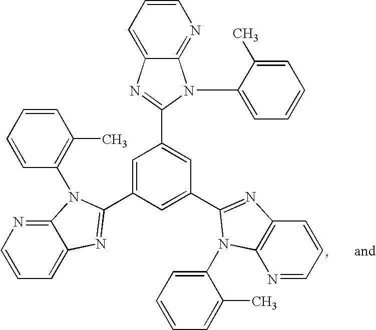
3,500 parts by mass of 1-butanol. The coated liquid was dried at 80° C. in vacuum for 2 hours to form the electron-transporting organic thin-film layer in a thickness of 15 mn on the temporary support.
(O) Production of Transfer Material O

Spin-coated onto one side of a 188-μm-thick temporary support made of polyether sulfone available from Sumitomo Bakelite Co., Ltd. was a coating solution for a hole-transporting, organic thin-film layer having a composition having 40 parts by mass of a hole-transporting compound (PTPDES) represented by the structural formula: 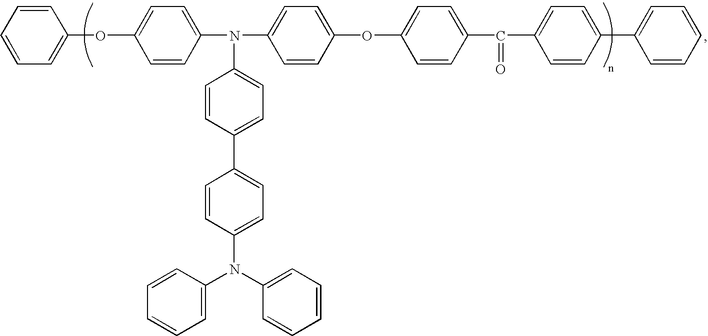
10 parts by mass of an additive (TBPA) represented by the structural
formula: 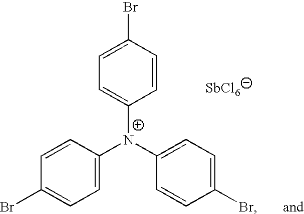
3,200 parts by mass of dichloroethane. The coated liquid was dried at room temperature to form a hole-transporting, organic thin-film layer in a thickness of 100 nm on the temporary support.
(P) Production of Organic EL Device
(1) Transfer of Organic Thin-Film Layer onto Laminate Surface

The transfer material M with its light-emitting, organic thin-film layer downward was overlapped on each Laminate A, B, K and L with its electrode upward, each Laminate C, D, E and F having an electron-transporting, organic thin-film layer, and each Laminate G, H, I and J having an hole-transporting, organic thin-film layer, with a top surface of its organic thin-film layer upward, and heated and pressed at 160° C., 0.3 MPa, and 0.05 m/min with a pair of heating rollers. By peeling temporary supports, laminates each having the light-emitting, organic thin-film layer formed on a top surface of each Laminate A to L on the electrode side were obtained. Each laminate was irradiated with ultraviolet rays of 254 nm by a handy UV lamp (UVGL-25, available from Funakoshi Co., Ltd.), to confirm by the naked eye that the light-emitting, organic thin-film layer was uniformly formed. The laminates each formed with the light-emitting, organic thin-film layer were designated as MA, MB, MC, MD, ME, MF, MG, MH, MI, MJ, MK and ML, respectively.

The transfer material N with its electron-transporting, organic thin-film layer downward was overlapped on each Laminate A and B with its electrode upward, each Laminate C, D, E and F with an electron-transporting, organic thin-film layer upward, and each Laminate MG, MH, MI, MJ, Mk and ML with a light-emitting, organic thin-film layer upward, and heated and pressed at 160° C., 0.3 MPa, and 0.05 m/min with a pair of heating rollers. By peeling temporary supports, laminates each having the electron-transporting, organic thin-film layer formed on a top surface of each Laminate A to F, MG to ML on the electrode side were obtained. Each laminate was irradiated with ultraviolet rays of 254 nm by a handy UV lamp (UVGL-25, available from Funakoshi Co., Ltd.), to confirm by the naked eye that the electron-transporting, organic thin-film layer was uniformly formed. The laminates each formed with an electron-transporting, organic thin-film layer were designated as NA, NB, NC, ND, NE, NF, NMG, NMH, NMI, NMJ, NMK and NML.

The transfer material O with its hole-transporting, organic thin-film layer downward was overlapped on each Laminate K and L with its electrode upward, each Laminate G, H, I and J with an hole-transporting, organic thin-film layer upward, and each Laminate MA, MB, MC, MD, ME and MF with a light-emitting, organic thin-film layer upward, and heated and pressed at 160° C., 0.3 MPa, and 0.05 m/min with a pair of heating rollers. By peeling temporary supports, Laminates G to L, MA to MF each having a hole-transporting, organic thin-film layer formed on a top surface on the electrode side were obtained. Each laminate was irradiated with ultraviolet rays of 254 nm by a handy UV lamp (UVGL-25, available from Funakoshi Co., Ltd.), to confirm by the naked eye that the hole-transporting, organic thin-film layer was uniformly formed. The laminates each formed with a hole-transporting, organic thin-film layer were designated as OG, OH, OI, OJ, OK, OL, OMA, OMB, OMC, OMD, OME and OMF.

(2) Bonding

The resultant laminates were overlapped in combinations shown in Table 1, such that electrodes were opposing via the light-emitting, organic thin-film layer, and each set of overlapped laminates was heated and pressed at 160° C., 0.3 MPa, and 0.05 m/min with a pair of heating rollers to bond layers, thereby producing organic EL devices. The order of bonding was (glass plate or polyimide film)/Al/LiF/(with or without electron-transporting, organic thin-film layer)/light-emitting, organic thin-film layer/(with or without hole-transporting, organic thin-film layer)/ITO/(glass plate or polyimide film). In the case of the organic EL device having a layer structure of glass plate/Al/LiF/(with or without electron-transporting, organic thin-film layer)/light-emitting, organic thin-film layer/(with or without hole-transporting, organic thin-film layer)/ITO/(glass plate or polyimide film), light may be taken out from the side of the glass plate or the polyimide film. In the example in which the light was taken out from the side of the glass plate, the thickness of the Al layer was 0.02 μm, and an 0.2-μm-thick ITO layer was disposed between the glass plate and the Al layer in the same manner as in the Laminates G to L.

(Q) Production of Samples of Comparative Examples

Spin-coated on the hole-transporting, organic thin-film layer of each resultant Laminate G-J, and on ITO of each resultant Laminate K, L was a coating solution for a light-emitting, organic thin-film layer having a composition having 40 parts by mass of polyvinyl carbazole having Mw of 63,000 available from Aldrich Chemical Co., 1 part by mass of tris(2-phenylpyridine) iridium complex (ortho-metallation complex), and 3,200 parts by mass of dichloroethane. The coated liquid was dried at room temperature to form a light-emitting, organic thin-film layer in a thickness of 13 nm, thereby producing Laminates QG to QL.

An electron-transporting compound having the structural formula: 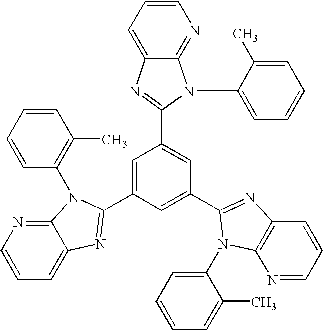
was vapor-deposited on the light-emitting, organic thin-film layer of each Laminate QG to QL in a reduced pressure atmosphere of about 0.1 mPa, to form an electron-transporting, organic thin-film layer having a thickness of 9 nm. Next, a patterned vapor deposition mask having a light-emitting area of 5 mm×5 mm was placed on the electron-transporting, organic thin-film layer, to vapor-deposit LiF as a dielectric layer in a thickness of 0.3 μm in a reduced pressure atmosphere of about 0.1 mPa. Further, Al was vapor-deposited as electrodes in the same pattern as the LiF layer, and aluminum lead wires were connected to the Al electrodes to produce Laminates QG-a to QL-a.

Spin-coated onto the light-emitting, organic thin-film layer of each Laminate QG to QL was a coating solution for an electron-transporting, organic thin-film layer having a composition having 10 parts by mass of polyvinylbutyral 2000L (Mw=2,000, available from Denki Kagaku Kogyo Kabushiki Kaisha), 20 parts by mass of an electron-transporting compound having the structure: 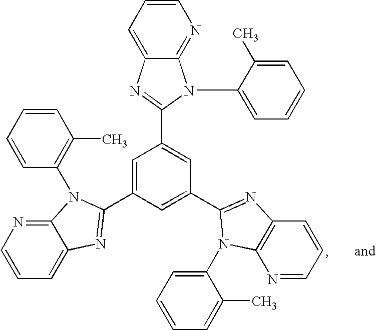
3,500 parts by mass of l-butanol. The coated liquid was dried at 80° C. in vacuum for 2 hours to form an electron-transporting, organic thin-film layer in a thickness of 15 nm. Next, with a patterned vapor deposition mask having a light-emitting area of 5 mm×5 mm placed on an electron-transporting, organic thin-film layer, LiF was vapor-deposited onto the Al layer in a thickness of 0.3 μm as a dielectric layer in a reduced pressure atmosphere of about 0.1 mPa. Further, Al was vapor-deposited as an electrode in the same pattern as that of the LiF layer, and aluminum lead wires were connected to the Al electrodes, thereby producing Laminates QG-b to QL-b.
(J) Evaluation

The resultant organic EL devices were evaluated by the following method. DC voltage was first applied to each organic EL device by Source-Measure Unit 2400 available from Toyo Corporation to cause light emission. Table 1 shows light-emitting efficiency at 200 cd/m² together with the layer structure. In Table 1, “/” means an interface between adjacent layers, “//” means an interface with which adjacent layers were bonded, and layers formed by a transferring step are underlined.

TABLE 1

| | | | Light-Emitting |
|---|---|---|---|
| Sample No. | One Laminate | Other Laminate | Efficiency⁽¹⁾ at 200 cd/m² |
| Example 1 | A | MG | 10.8% |
| Example 2 | B | MK | 7.9% |
| Example 3 | C | MJ | 15.1% |
| Example 4 | D | NMI | 15.0% |
| Example 5 | E | ML | 11.4% |
| Example 6 | F | MI | 15.3% |
| Example 7 | MA | I | 11.2% |
| Example 8 | MB | MG | 11.2% |
| Example 9 | MC | MH | 15.4% |
| Example 10 | MD | OG | 14.8% |
| Example 11 | ME | J | 14.7% |
| Example 12 | MF | MI | 15.0% |
| Example 13 | OMA | H | 11.2% |
| Example 14 | OMB | K | 11.1% |
| Example 15 | OMD | OG | 15.1% |
| Example 16 | OMD | I | 15.0% |
| Example 17 | NC | NMG | 14.9% |
| Example 18 | NE | MG | 14.8% |
| Example 19 | MD | G | 15.0% |
| Example 20 | MD | K | 14.9% |
| Com. Ex. 1 | QG-a | Not bonded | 14.9% |
| Com. Ex. 2 | QH-a | Not bonded | 14.5% |
| Com. Ex. 3 | QI-b | Not bonded | 15.1% |
| Com. Ex. 4 | QL-b | Not bonded | 11.0% |

Note:
⁽¹⁾External quantum efficiency.

| No. | Layer Structure |
|---|---|
| Example 1 | Glass⁽¹⁾/Al/LiF//EL⁽²⁾/HTL⁽³⁾/ITO/Glass |
| Example 2 | Polyimide/Al/LiF//EL/ITO/Glass |
| Example 3 | Glass/ITO/Al/LiF/ETL⁽⁴⁾//EL/HTL/ITO/Polyimide |
| Example 4 | Polyimide/Al/LiF/ETL//ETL/EL/HTL/ITO/Glass |
| Example 5 | Glass/ITO/Al/LiF/ETL//EL/ITO/Polyimide |
| Example 6 | Polyimide/Al/LiF/ETL//EL/HTL/ITO/Glass |
| Example 7 | Glass/Al/LiF/EL//HTL/ITO/Glass |
| Example 8 | Polyimide/Al/LiF/EL//EL/HTL/ITO/Glass |
| Example 9 | Glass/ITO/Al/LiF/ETL/EL//EL/HTL/ITO/Polyimide |
| Example 10 | Polyimide/Al/LiF/ETL/EL//HTL/HTL/ITO/Glass |
| Example 11 | Glass/ITO/Al/LiF/ETL/EL//HTL/ITO/Polyimide |
| Example 12 | Polyimide/Al/LiF/ETL/EL//EL/HTL/ITO/Glass |
| Example 13 | Glass/ITO/Al/LiF/EL/HTL//HTL/ITO/Polyimide |
| Example 14 | Polyimide/Al/LiF/EL/HTL//ITO/Glass |
| Example 15 | Polyimide/Al/LiF/ETL/EL/HTL//HTL/HTL/ITO/Glass |
| Example 16 | Polyimide/Al/LiF/ETL/EL/HTL//HTL/ITO/Glass |
| Example 17 | Glass/Al/LiF/ETL/ETL//ETL/EL/HTL/ITO/Glass |
| Example 18 | Glass/Al/LiF/ETL/ETL//EL/HTL/ITO/Glass |
| Example 19 | Polyimide/Al/LiF/ETL/EL//HTL/ITO/Glass |
| Example 20 | Polyimide/Al/LiF/ETL/EL//ITO/Glass |
| Com. Ex. 1 | Al/LiF/ETL/EL/HTL/ITO/Glass |
| Com. Ex. 2 | Al/LiF/ETL/EL/HTL/ITO/Polyimide |
| Com. Ex. 3 | Al/LiF/ETL/EL/HTL/ITO/Glass |
| Com. Ex. 4 | Al/LiF/ETL/EL/ITO/Polyimide |

Note
⁽¹⁾Glass plate.
⁽²⁾Light-emitting, organic thin-film layer.
⁽³⁾Hole-transporting, organic thin-film layer.
⁽⁴⁾Electron-transporting, organic thin-film layer.

Because the organic thin-film devices of Examples were produced from both electrode sides, their productivity was higher than that of the organic thin-film devices of Comparative Examples (conventional methods), which were laminated from one side. Observation by a 50-times magnifier showed that any of the organic thin-film devices obtained in Examples had uniform light emission.

Further, by carrying out the transfer of organic thin-film layers in the same manner as in Examples except for using a continuous polyimide web having a thickness of 75 μm as a substrate in place of a glass plate or a polyimide film in a rectangular shape, the same results were obtained with good productivity.

The same results were also obtained by using a composite film comprising 50-μm-thick polyimide films (UPILEX-50S available from Ube Industries, Ltd.) bonded to both sides of a commercially available 30-μm-thick aluminum foil by a commercially available adhesive as a substrate in place of a 50-μm-thick polyimide film (UPILEX-50S, available from Ube Industries, Ltd.).

By using the method of the present invention comprising a peeling transfer method and a bonding method using a transfer material having an organic thin-film layer (constituting the organic thin-film device) coated onto a temporary support by a wet method, it is possible to produce organic thin-film devices such as organic EL devices, etc. having excellent light-emitting efficiency with high productivity at low cost. Particularly because the method in which an organic thin-film layer is once coated onto a temporary support is used, the organic thin-film layer can be made extremely thinner than that obtained by a thermal transfer method by a laser (laser abrasion), resulting in excellent uniformity of light emission.

1. A method for producing an organic thin-film device comprising the steps of (a) heating and/or pressing a transfer material having an organic thin-film layer formed on a temporary support and a first laminate comprising a substrate and at least a transparent conductive layer or a rear-surface electrode formed on said substrate, which are overlapped each other such that said organic thin-film layer of said transfer material faces a receiving surface of said first laminate, thereby forming a laminate structure; (b) peeling said temporary support from said laminate structure to transfer said organic thin-film layer to said receiving surface of said first laminate; and (c) bonding a second laminate comprising a substrate and at least a rear-surface electrode or a transparent conductive layer formed on said substrate to said organic thin-film layer transferred onto said first laminate.

2. The method of claim 1, wherein said step (a) comprises heating and pressing.

3. The method of claim 1 or 2, wherein the heating is carried out by a heating means selected from the group consisting of a laminator, an infrared heater and a roller heater.

4. The method of claim 1, wherein said transfer material is formed by a wet method.

5. The method of claim 1, wherein said second laminate has an organic thin-film layer formed on said rear-surface electrode or said transparent conductive layer.

6. The method of claim 1, wherein said first laminate and said second laminate respectively have a thermal expansion coefficient of 20 ppm/° C. or less.

7. The method of claim 1, wherein said organic thin-film layer contains at least a light-emitting, organic compound or a carrier-transporting, organic compound.

8. The method of claim 1, wherein a hole-transporting, organic thin-film layer, a light-emitting, organic thin-film layer and an electron-transporting, organic thin-film layer are successively transferred.

9. The method of claim 1, wherein at least one of said first substrate and said second substrate is provided with a transparent conductive layer.

10. The method of claim 1, wherein at least one of said temporary support and said substrate is in the form of a continuous web.

11. The method of claim 1, wherein said substrate is made of at least one material selected from the group consisting of polyimides; polyesters; polycarbonates; polyether sulfone; metal foils such as aluminum foil, copper foil, stainless steel foil, gold foil, silver foil; plastic sheets of liquid crystal polymers; fluorine-containing polymers such as poly(chlorotrifluoroethylene), Teflon, polytetrafluoroethylene-polyethylene copolymers.

12. An organic thin-film device produced by the method of claim 1.

13. A method for producing an organic electroluminescent device comprising the steps of (a) heating and/or pressing a transfer material having an organic thin-film layer formed on a temporary support and a first laminate comprising a substrate and at least a transparent conductive layer or a rear-surface electrode formed on said substrate, which are overlapped each other such that said organic thin-film layer of said transfer material faces a receiving surface of said first laminate, thereby forming a laminate structure; (b) peeling said temporary support from said laminate structure to transfer said organic thin-film layer to said receiving surface of said first laminate; and (c) bonding a second laminate comprising a substrate and at least a rear-surface electrode or a transparent conductive layer formed on said substrate to said organic thin-film layer transferred onto said first laminate.

14. The method of claim 13, wherein said step (a) comprises heating and pressing.

15. The method of claim 13 or 14, wherein a heating means is selected from the group consisting of a laminator, an infrared heater and a roller heater.

16. The method of claim 13, wherein said second laminate has an organic thin-film layer formed on said rear-surface electrode or said transparent conductive layer.
